(19) United States
(12) Patent Application Publication
(10) Pub. No.: US 2023/0343885 A1
(43) Pub. Date: Oct. 26, 2023

(54) IMAGE SENSOR STRUCTURE

(71) Applicant: Taiwan Semiconductor Manufacturing Company, Ltd., Hsinchu (TW)

(72) Inventors: Hsiang-Lin Chen, Hsinchu (TW); Sin-Yi Jiang, Hsinchu (TW); Sung-Wen Huang Chen, Hsinchu (TW); Yin-Kai Liao, Taipei City (TW); Jung-I Lin, Hsinchu (TW); Yi-Shin Chu, Hsinchu City (TW); Kuan-Chieh Huang, Hsinchu City (TW)

(21) Appl. No.: 17/835,049

(22) Filed: Jun. 8, 2022

Related U.S. Application Data
(60) Provisional application No. 63/333,440, filed on Apr. 21, 2022.

(51) Int. Cl. H01L 31/103; H01L 31/0288; H01L 31/18

(52) U.S. Cl. CPC H01L 31/103; H01L 31/0288; H01L 31/1804

(57) ABSTRACT

Image sensors and methods of forming the same are provided. An image sensor according to the present disclosure includes a silicon substrate, a germanium region disposed in the silicon substrate, a doped semiconductor isolation layer disposed between the silicon substrate and the germanium region, a heavily p-doped region disposed on the germanium region, a heavily n-doped region disposed on the silicon substrate, a first n-type well disposed immediately below the germanium region, a second n-type well disposed immediately below the heavily n-doped region, and a deep n-type well disposed below and in contact with the first n-type well and the second n-type well.

This application is a non-provisional application of and claims benefit of U.S. Provisional Patent Application Ser. No. 63/333,440, filed Apr. 21, 2022, the entire disclosure of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process, such that realizing continued advances in ICs calls for similar advances in semiconductor manufacturing processes and technology.

As one example, semiconductor sensors are widely used for a variety of applications to measure physical, chemical, biological, and/or environmental parameters. Some specific types of semiconductor sensors include gas sensors, pressure sensors, temperature sensors, and image sensors, among others. For image sensors, dark current is a major concern for performance and reliability. Dark current, which is current that flows in the absence of light, can more generally be described as leakage current present in an image sensor. In at least some cases where a low bandgap semiconductor material is used, the low bandgap semiconductor material or its interface with a substrate may result in significant dark current. Although existing optical image sensors and methods for fabricating such have been generally adequate for their intended purpose, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method 100 for fabricating a photosensitive device, according to various aspects of the present disclosure.

FIGS. 2-11 are fragmentary cross-sectional views of a workpiece, at various fabrication stages of the method 100 in FIG. 1, according to various aspects of the present disclosure.

FIGS. 12-14 are fragmentary cross-sectional views of various example photosensitive devices, according to various aspects of the present disclosure.

FIGS. 15-17 are fragmentary schematic top views of various example photosensitive devices, according to various aspects of the present disclosure.

FIG. 18 is a flow chart of a method 300 for fabricating a photosensitive device, according to various aspects of the present disclosure.

FIGS. 19-26 are fragmentary cross-sectional views of a workpiece, at various fabrication stages of the method 300 in FIG. 17, according to various aspects of the present disclosure.

FIGS. 27-29 are fragmentary cross-sectional views of various example photosensitive devices, according to various aspects of the present disclosure.

FIGS. 30-32 are fragmentary schematic top views of various example photosensitive devices, according to various aspects of the present disclosure.

FIGS. 33 and 34 are fragmentary schematic top views of photosensitive pixel designs, according to various aspects of the present disclosure.

FIG. 35 illustrates an example stacked image sensor that includes image sensors according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Some image sensors or photosensitive devices include a semiconductor structure of a first semiconductor material disposed in a semiconductor substrate of a second semiconductor material different from the first semiconductor material. In most cases, the first semiconductor material may have a smaller band gap or is more sensitive to incident light than the second semiconductor material. Due to its photosensitivity and its junction with the semiconductor substrate, dark current level may become higher, reducing the signal-to-noise ratio (SNR).

The present disclosure provides an image sensor structure where the metal connections that generate the electric field to move photon electrons are disposed in different semiconductor regions. In an example structure, a germanium (Ge) photo sensing region is disposed in a silicon (Si) substrate. A deep well is disposed in the silicon substrate and at least partially extends below the germanium photo sensing region. A first metal connection is made to the germanium photo-sensing region while a second metal connection is made directly to the deep well through the silicon substrate. That is, not all of the first metal connection and the second metal connection are made directly to the germanium photo-sensing region. Because the two metal connections are made to different semiconductor regions, electron transfer paths are moved farther away from the germanium photo-sensing region and dark current can be greatly reduced.

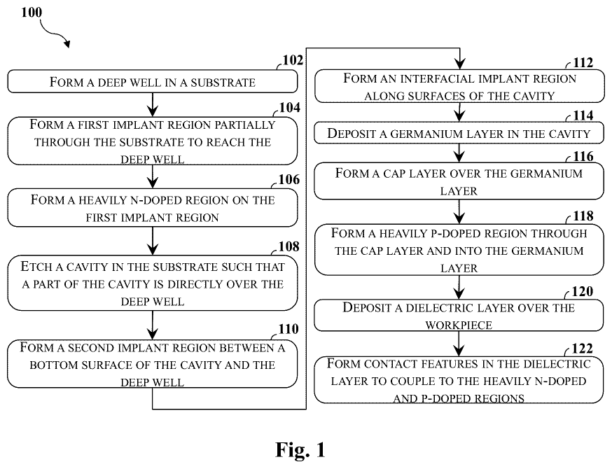

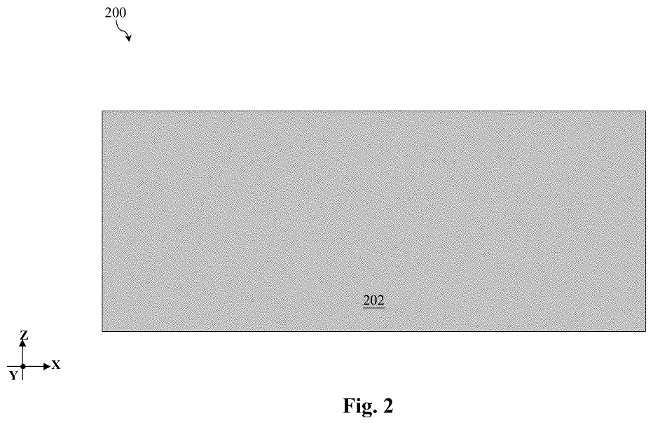

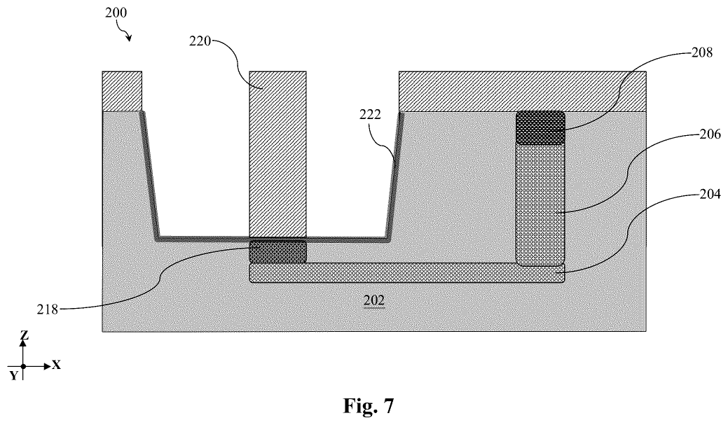

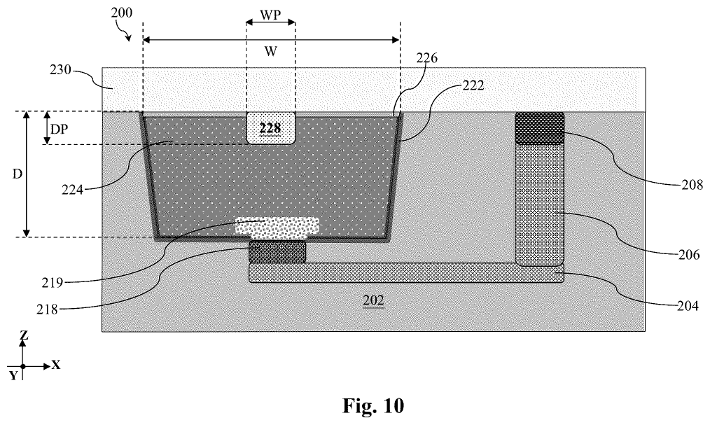

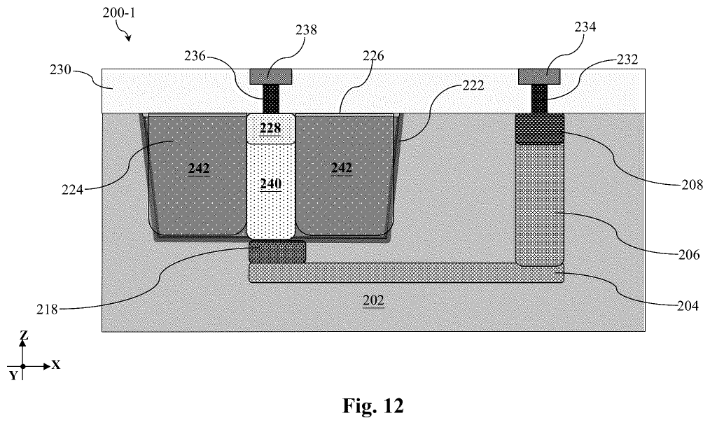

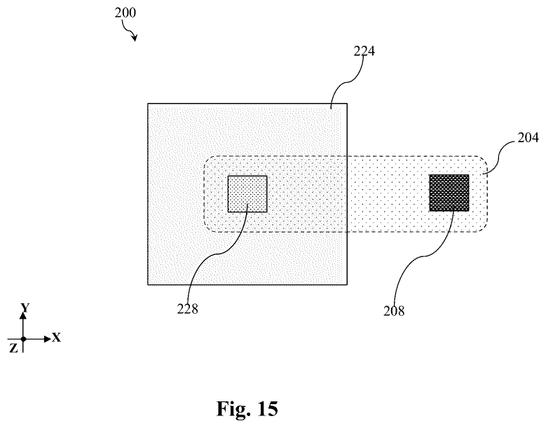

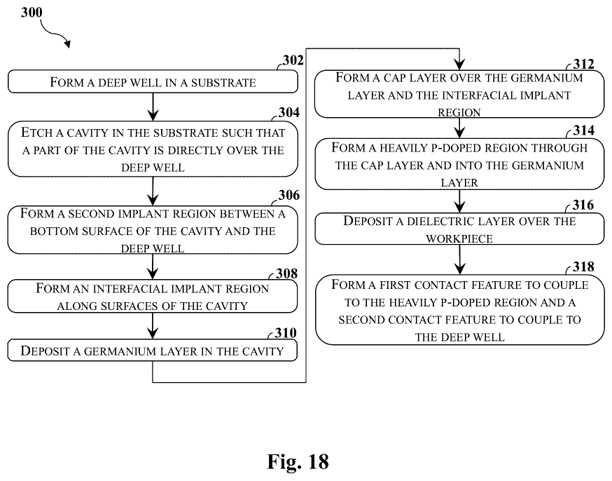

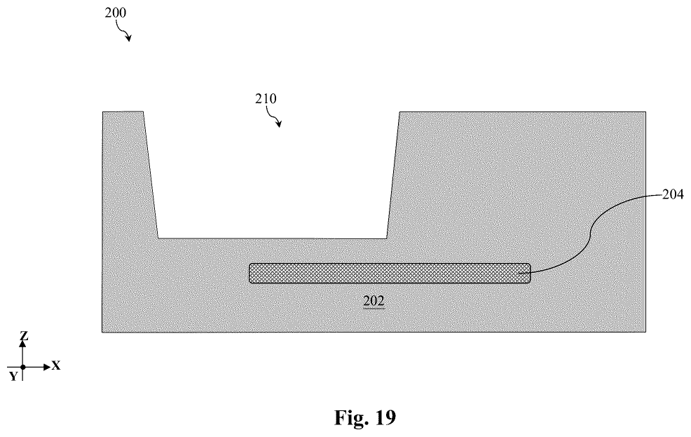

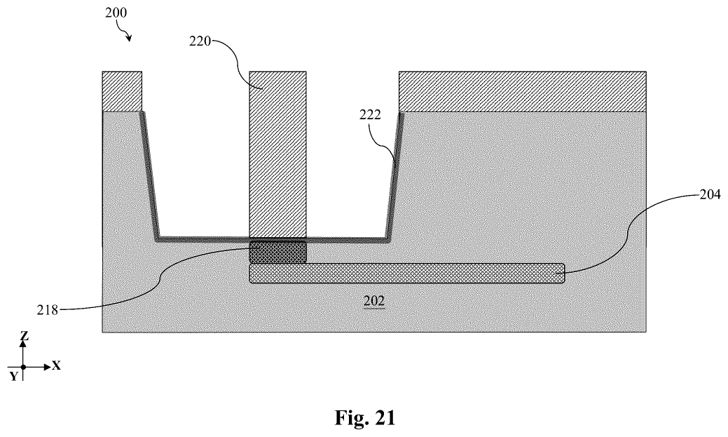

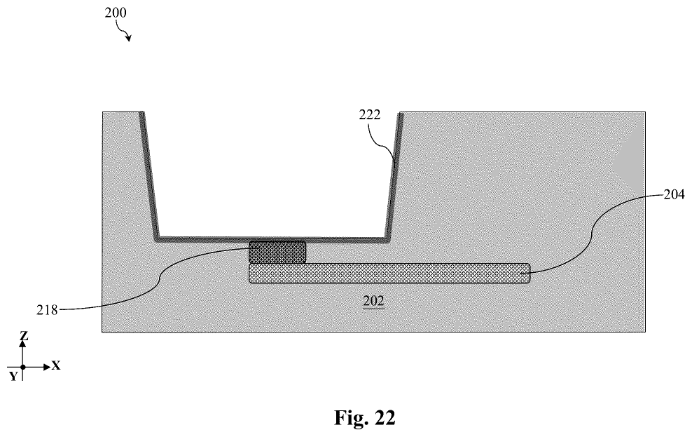

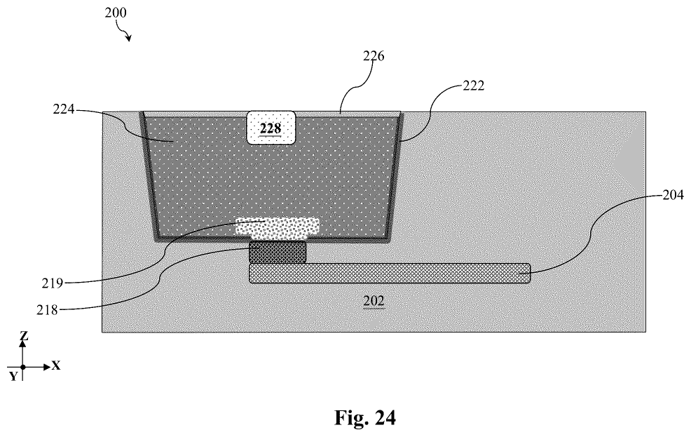

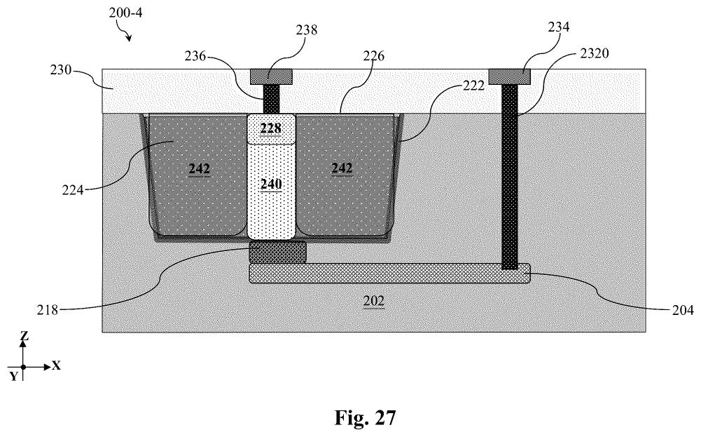

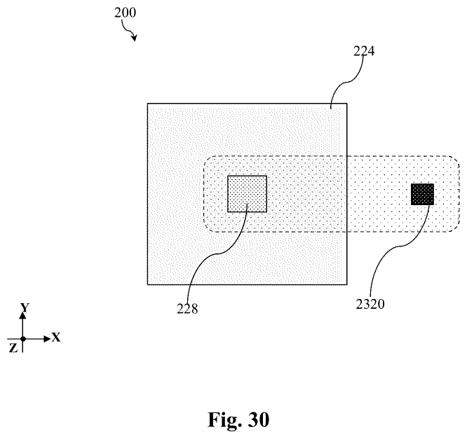

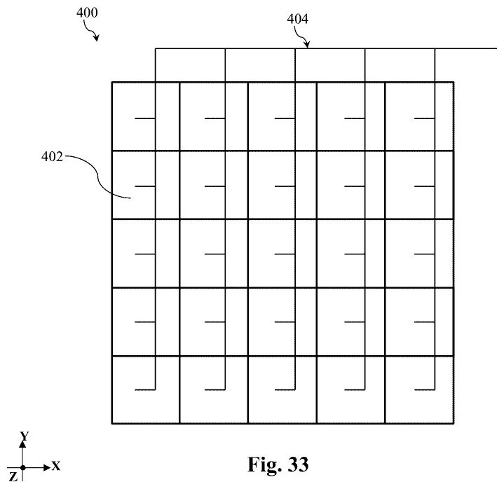

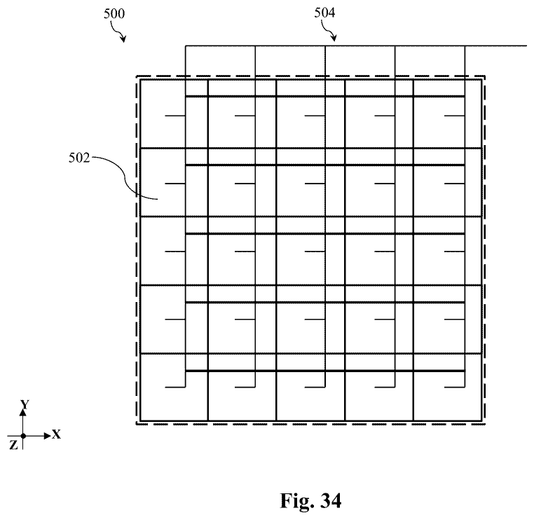

The various aspects of the present disclosure will now be described in more detail with reference to the figures. FIGS. 1 and 18 illustrate flowcharts of a method 100 and a method 300 of forming an image sensor structure. Methods 100 and 300 are merely examples and are not intended to limit the present disclosure to what is explicitly illustrated therein. Additional steps may be provided before, during and after methods 100 and 300, and some steps described can be replaced, eliminated, or moved around for additional embodiments of the methods. Not all steps are described herein in detail for reasons of simplicity. Method 100 is described below in conjunction with FIGS. 2-11, which illustrate fragmentary cross-sectional views of a workpiece 200 at different stages of fabrication according to embodiments of method 100. FIGS. 12-14 provide alternative embodiments to the workpiece 200 shown in FIG. 10. FIGS. 15-17 illustrate schematic top views of the workpiece 200 to illustrate various example configurations to improve electron transfer efficiency. Method 300 is described below in conjunction with FIGS. 19-26, which illustrate fragmentary cross-sectional views of a workpiece 200 at different stages of fabrication according to embodiments of method 300. FIGS. 27-29 provide alternative embodiments to the workpiece 200 shown in FIG. 24. FIGS. 30-32 illustrate schematic top views of the workpiece 200 to illustrate various example configurations to improve electron transfer efficiency. FIGS. 33 and 34 illustrate fragmentary schematic top views of photosensitive pixel designs. Because a photosensitive device or an image sensor structure will be formed from the workpiece 200, the workpiece 200 may be referred to as a photosensitive device 200, an image sensor 200, or an image sensor structure 200 as the context requires. Throughout FIGS. 2-17 and 19-34, the X direction, the Y direction, and the Z direction are perpendicular to one another and are used consistently. For example, the X direction in one figure is parallel to the X direction in a different figure. Additionally, throughout the present disclosure, like reference numerals are used to denote like features.

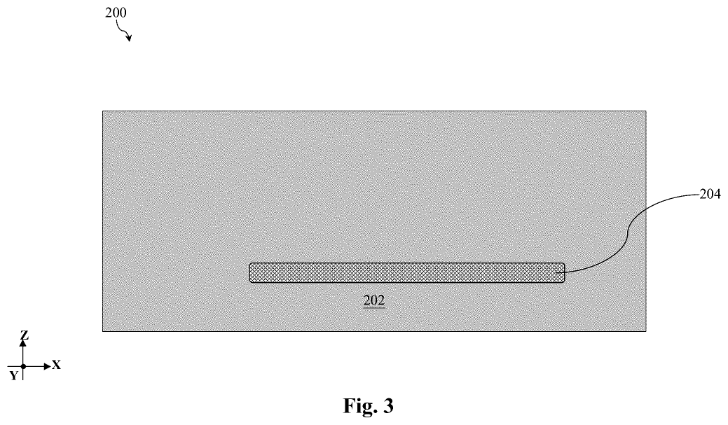

Referring to FIGS. 1, 2 and 3, method 100 includes a block 102 where a deep well 204 is formed in a substrate 202 of a workpiece 200. Operations at block 102 may include receiving the substrate 202 (shown in FIG. 2) and forming the deep well 204 in the substrate 202 (shown in FIG. 3). Because more layers and features are to be formed over or in the substrate 202, the substrate 202 and all features formed thereon may be generally referred to as a workpiece 200. Referring to FIG. 2, the substrate 202 is received. The substrate 202 may be a silicon (Si) substrate. In some alternative embodiments, the substrate 202 may be a silicon-on-insulator (SOI) substrate with a buried oxide (BOX) layer. Referring to FIG. 3, the deep well 204 is formed in the substrate 202. In some embodiments represented in the figures, the deep well 204 is an n-type well. Because the deep well 204 is formed in the substrate 202, it may be referred to as a deep silicon n-well (DSNW) 204 or deep n-well (DNW) 204. In an example process, a screen oxide layer (not explicitly shown) is first deposited over the substrate 202 and a patterned photoresist layer is formed over the screen oxide to cover regions of the workpiece 200 that are not to be implanted. With the patterned photoresist layer in place, the workpiece 200 is implanted with an n-type dopant, such as phosphorus (P) or arsenic (As). After the implantation, the n-type dopant are thermally driven further into the substrate 202 by an anneal process. In some instances, the deep well 204 may include a dopant concentration between about 1×10¹⁶ cm⁻³ to about 9×10¹⁸ cm⁻³. As will be described further below and illustrated in FIG. 15, 16, or 17 to have an elongated shape that extends lengthwise along the X direction. The deep well 204 will serve a part of a conduction path for collected photon electrons.

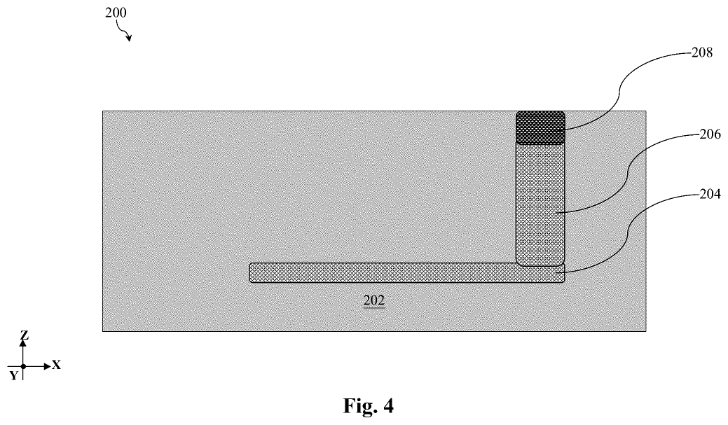

Referring to FIGS. 1 and 4, method 100 includes a block 104 where a first implant region 206 is formed to partially extend through the substrate 202 to reach the deep well 204. In the depicted embodiment, the first implant region 206 extends from a top surface of the substrate 202 vertically down to couple to or overlap with an end of the deep well 204. Like the deep well 204, the first implant region 206 provides a vertical conduction path from the deep well 204 to the top surface of the substrate 202 and is also a part of the conduction path for collected photon electrons. The first implant region 206 may also be referred to as silicon n-well (SNW) or n-well (NW). In an example process, a screen oxide layer (not explicitly shown) is first deposited over the substrate 202 and a patterned photoresist layer is formed over the screen oxide to cover regions of the workpiece 200 that are not to be implanted. With the patterned photoresist layer in place, the workpiece 200 is implanted with an n-type dopant, such as phosphorus (P) or arsenic (As). During the implantation, the n-type dopant are thermally driven further into the substrate 202 to reach the deep well 204 by an anneal process. In some instances, the first implant region 206 may include a dopant concentration of about 1×10¹⁶ cm⁻³ to about 9×10¹⁸ cm⁻³. Different from the deep well 204, the first implant region 206 extends along a vertical direction perpendicular to a top surface of the substrate 202.

Referring to FIGS. 1 and 4, method 100 includes a block 106 where a heavily n-doped region 208 is formed on the first implant region 206. The heavily n-doped region 208 serves to reduce contact resistance when interfacing with a metal contact feature. The heavily n-doped region 208 may be formed by ion implantation. In some embodiments, the heavily n-doped region 208 includes an n-type dopant, such as phosphorus (P) or arsenic (As). As its name suggests, a dopant concentration of the heavily n-doped region 208 is greater than the dopant concentration in the first implant region 206. In some implementations, the dopant concentration in the heavily n-doped region 208 is between about 1×10¹⁷ cm⁻³ and about 9×10²⁰ cm⁻³. As represented by the illustration in FIG. 4, the heavily n-doped region 208 may vertically overlap with the first implant region 206 and is disposed adjacent the top surface of the substrate 202.

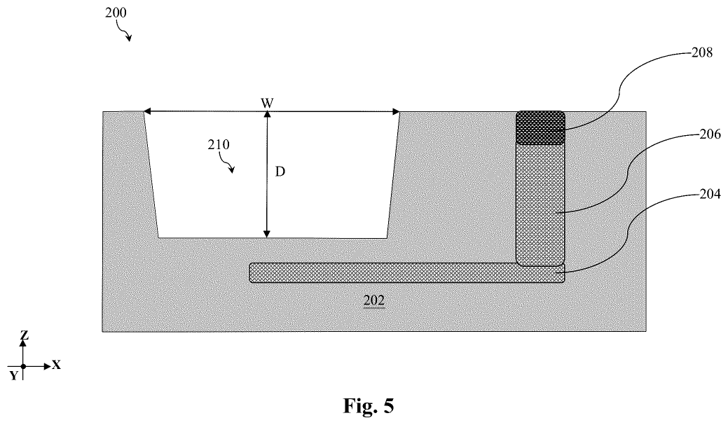

Referring to FIGS. 1 and 5, method 100 includes a block 108 where a cavity 210 is etched in the substrate 202 such that a part of the cavity 210 is directly over the deep well 204. Although not explicitly shown in the figures, photolithography and etch processes may be used to form the cavity 210 in the substrate 202. In an example process, a hard mask layer is deposited over the substrate 202 using CVD or a suitable deposition method. A photolithography process is then performed to form a patterned photoresist layer over the hard mask layer. The hard mask is then etched using the patterned photoresist as an etch mask to form a patterned hard mask. The patterned hard mask is then applied as an etch mask to etch the substrate 202 to form the cavity 210. The hard mask is formed of a material different from that of the substrate 202. In some examples, the hard mask may include silicon oxide, silicon nitride, or a combination thereof. As shown in FIG. 5, the cavity 210 may have a depth D along the Z direction and a top width W along the X direction. In some embodiments, the depth D is about 900 nm to about 2100 nm. In some embodiments, the top width W is about 2000 nm to about 10000 nm. A suitable etch process to form the cavity 210 may be a dry etch process, a wet etch process, or a combination thereof.

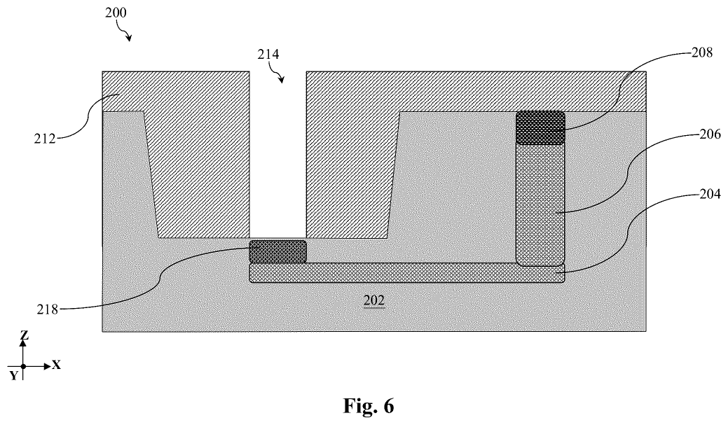

Referring to FIGS. 1 and 6, method 100 includes a block 110 where a second implant region 218 is formed between a bottom surface of the cavity 210 and the deep well 204. The second implant region 218 serves as a conduction path for photon electrons between the bottom surface of the cavity 210 to the deep well 204. As shown in FIG. 6, both the first implant region 206 and the second implant region 218 are coupled to or overlap with the deep well 204. In some embodiments represented in FIG. 6, both the first implant region 206 and the second implant region 218 are doped with an n-type dopant. In some implementations, the second implant region 218 and first implant region 206 have the same dopant concentration. In an example process to form the second implant region 218, a first patterned implantation mask 212 is first formed over the workpiece 200, including over the cavity 210. As shown in FIG. 6, the first patterned implantation mask 212 has an opening 214 that exposes the implantation area for block 110. In some instances, the first patterned implantation mask 212 may be a photoresist layer or a bottom antireflective coating (BARC) layer. In the depicted embodiments, the first patterned implantation mask 212 is a photoresist layer. With the first patterned implantation mask 212 put in place, an ion implantation process is performed to form the second implant region 218. After the second implant region 218 is formed, the first patterned implantation mask 212 may be removed by ashing or selective etching.

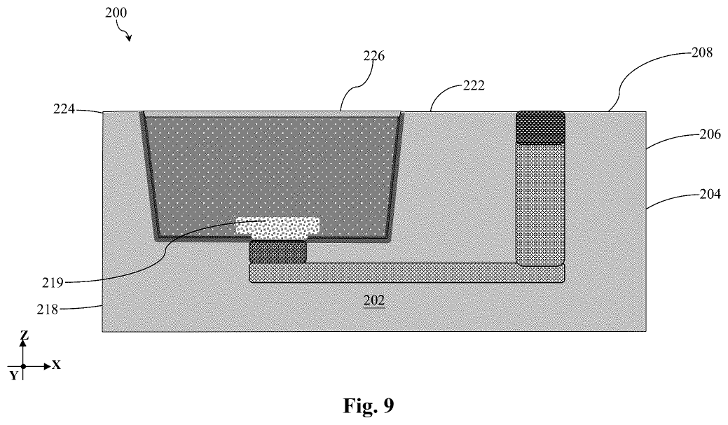

In some embodiments represented in FIG. 6, the second implant region 218 is thermally driven such that it is slightly removed from the bottom surface of the cavity 210. This prevents too much n-type dopant from diffusing into the to-be-formed germanium layer 224 (shown in FIG. 9) in subsequent processes or thermal cycles. While some n-type dopant diffusion into the germanium layer 224 may facilitate photon electron collection, it may increase dark current. The controlled n-type dopant diffusion into the germanium layer 224 is also the reason why the germanium layer 224 is not made to directly land on the deep well 204 to increase contact area. Larger contact area may lead to excessive n-type dopant diffusion, causing an undesirable level of dark current. While not explicitly shown in FIG. 6, the second implant region 218 is disposed directly below only a small central region of the cavity 210. The small and controlled engagement area between the germanium layer 224 and the second implant region 218 reduces n-type dopant diffusion into the germanium layer 224 to prevent excessive dark current increase.

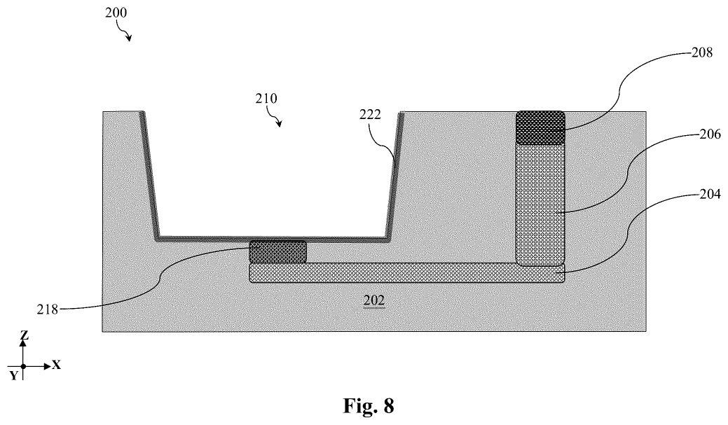

Referring to FIGS. 1, 7 and 8, method 100 includes a block 112 where an interfacial implant region 222 is formed along surfaces of the cavity 210. The interfacial implant region 222 serves at least two functions. First, the interfacial implant region 222 may bridge the lattice mismatch between silicon in the substrate 202 and the to-be-formed germanium layer 224 (shown in FIG. 9). Because of a 4.2% lattice mismatch between lattices of silicon and lattices of germanium, lattice mismatch defects, such as line defects, may commence near the Si—Ge interface and permeate through the germanium layer 224, giving rise to additional dark current. It is observed that forming a p-doped region near the Si—Ge interface may greatly reduce the effect of lattice mismatch. Second, the interfacial implant region 222 may act as a trap of photon electron to prevent photon electrons from entering into the substrate 202. In an example process to form the interfacial implant region 222, a second patterned implantation mask 220 is formed over the workpiece 200 to protect the top surface of the substrate 202 as well as the second implant region 218. As the second patterned implantation mask 220 may share similar properties with the first patterned implantation mask 212, detailed description thereof is omitted for brevity. An ion implantation process is performed to dope uncovered surfaces of the cavity 210 with a p-type dopant, such as boron (B) or boron difluoride (BF₂), to form the interfacial implant region 222. In some embodiments, despite the use of the second patterned implantation mask 220, the interfacial implant region 222 may at least partially extend into the bottom surface of the cavity 210 and the second implant region 218. Compared to the other doped regions, the interfacial implant region 222 is quite thin, with a thickness between about 20 nm and about 100 nm. The interfacial implant region 222 may have a dopant concentration between about 5×10¹⁶ atoms/cm³ (cm⁻³) and about 1×10¹⁹ cm^{31 3}. As shown in FIG. 8, after the second implant region 218 and the interfacial implant region 222 are formed, the second patterned implantation mask 220 may be removed by ashing or selective etching.

Referring to FIGS. 1 and 9, method 100 includes a block 114 where a germanium layer 224 is formed in the cavity 210. After the formation of the interfacial implant region 222, the germanium layer 224 is formed in and fills a remainder of the cavity 210. The germanium layer 224 is formed directly on the interfacial implant region 222 and is spaced apart from the substrate 202 by the interfacial implant region 222. Because the interfacial implant region 222 hardly takes up any space in the cavity 210, the germanium layer 224 may have similar depth D and top width W with the cavity 210. That is, the germanium layer 224 may have a depth D between about 900 nm and about 2100 nm and a top width W between about 2000 nm and about 10000 nm. In some embodiments, the germanium layer 224 is undoped (or unintentionally doped (UID)) (i.e., the germanium layer 224 is substantially free of dopant). In some embodiments, the germanium layer 224 has a dopant concentration that is considered undoped. In some alternative embodiments, the germanium layer 224 may be replaced with other semiconductor materials with a bandgap smaller than that of silicon or with a direct bandgap. For example, the germanium layer 224 may be replaced with a gallium antimony (GaSb) layer, a lead selenide (PbSe) layer, a lead telluride (PbTe) layer, a lead sulfide (PbS), indium phosphide (InP) layer, a gallium arsenide (GaAs) layer, a cadmium telluride (CdTe) layer, or a cadmium selenide (CdSe) layer.

In some embodiments, the germanium layer 224 is formed by a deposition process that selectively grows germanium on the interfacial implant region 222 without growing germanium on a patterned dielectric layer formed on top surfaces of the substrate 202. For example, the germanium layer 224 is formed by epitaxially growing germanium from the interfacial implant region 222, while little or no germanium is epitaxially deposited on the patterned dielectric layer. In some instances, the patterned dielectric layer may include silicon oxide. An epitaxy process for forming the germanium layer 224 can implement CVD deposition techniques (for example, VPE, UHV-CVD, LPCVD, and/or PECVD), molecular beam epitaxy, other suitable SEG processes, or combinations thereof. The epitaxy process can use gaseous and/or liquid precursors. For example, the epitaxy process uses a use a germanium-containing precursor (for example, germane (GeH₄), digermane (Ge₂H₆), germanium tetrachloride (GeCl₄), germanium dichloride (GeCl₂), other suitable germanium-containing precursor, or combinations thereof) and a carrier precursor (for example, a hydrogen precursor (e.g., H₂), an argon precursor (e.g., Ar), a helium precursor (e.g., He), a nitrogen precursor (e.g., N₂), a xenon precursor, other suitable inert precursor, or combinations thereof). In some embodiments, the epitaxy process is performed until epitaxially grown germanium substantially fills the cavity 210. A planarization process, such as a chemical mechanical polishing (CMP), can be performed to remove excess epitaxially grown germanium to provide a planar top surface.

Referring to FIGS. 1 and 9, method 100 includes a block 116 where a cap layer 226 is formed over the germanium layer 224. While not explicitly shown in the figures, the CMP process performed at block 114 may remove the germanium layer 224 at a faster rate, thereby forming a recess directly over the germanium layer 224. That is, the top surface of the germanium layer 224 is lower than the top surface of the substrate 202 after the CMP process. At block 116, an undoped (or UID) cap layer 226 is formed over the germanium layer 224. In the depicted embodiment, the cap layer 226 is undoped silicon layers (i.e., silicon layers that are substantially free of dopant, such as n-type dopant (e.g., phosphorous) or p-type dopant (e.g., boron)). In some embodiments, the cap layer 226 has a dopant concentration that is considered undoped. In an example process, the cap layer 226 is formed by a deposition process that selectively grows silicon on the germanium layer 224 while the substrate 202 is covered by a patterned dielectric layer. The patterned dielectric layer used at block 116 may be different from or the same as the patterned dielectric layer used at block 114. For example, the cap layer 226 is formed by epitaxially growing silicon from the germanium layer 224. An epitaxy process for forming cap layer 226 can implement CVD deposition techniques (for example, VPE, UHV-CVD, LPCVD, and/or PECVD), molecular beam epitaxy, other suitable SEG processes, or combinations thereof. The epitaxy process can use gaseous and/or liquid precursors, such as a silicon-containing precursor and a carrier precursor, such as those described herein. In some embodiments, a planarization process, such as CMP, may optionally performed to remove excess cap layer 226 to provide a planar top surface.

As shown in FIG. 9, thermal energy generated during the formation of the germanium layer 224 may cause the n-type dopant in the second implant region 218 to diffuse into germanium layer 224 to form an n-type diffusion region 219. The dopant concentration in the n-type diffusion region 219 is smaller than that in the second implant region 218. The n-type diffusion region 219 may facilitate the collection of photon electrons generated in the germanium layer 224.

Referring to FIGS. 1 and 10, method 100 includes a block 118 where a heavily p-doped region 228 is formed through the cap layer 226 and into the germanium layer 224. The heavily p-doped region 228 serves to reduce contact resistance when interfacing with a metal contact feature approaching from above. The heavily p-doped region 228 may be formed by ion implantation. In some embodiments, the heavily p-doped region 228 includes a p-type dopant, such as boron (B) or boron difluoride (BF₂). As its name suggests, a dopant concentration of the heavily p-doped region 228 is greater than the dopant concentration in the interfacial implant region 222. In some implementations, the dopant concentration in the heavily p-doped region 228 is between about 1×10¹⁷ cm⁻³ and about 1×10²¹ cm⁻³. As represented by the illustration in FIG. 10, the heavily p-doped region 228 extends completely through the cap layer 226 and terminates in the germanium layer 224.

As shown in FIG. 10, the heavily p-doped region 228 has a width WP along the X direction and a depth DP along the Z direction. As compared to the width W of the cavity 210 or the germanium layer 224, the width WP may be between about 0.3 times of W and about 1.5 times of W. That is, a ratio of the width WP to the width W may be between about 0.3 and about 1.5. Although not explicitly illustrated in the figures, the heavily p-doped region 228 may have a greater width and a greater area than the germanium layer 224 such that the entirety of the germanium layer 224 is disposed below the heavily p-doped region 228. This width ratio range is not trivial. When the ratio falls below 0.3, the heavily p-doped region 228 may not generate an electric field that can adequately drive photon electrons towards the second implant region 218. When the ratio is greater than 1.5, the heavily p-doped region 228 may take too much space to increase the pixel size. As compared to the depth D of the cavity 210 or the germanium layer 224, the depth DP may be between about 0.1 times of D and about 0.5 times of D. That is, a ratio of the depth DP to the depth D may be between about 0.1 and about 0.5. The depth ratio range is not trivial either. When the ratio falls below 0.1, the heavily p-doped region 228 may not generate a strong enough electric field that can adequately drive photon electrons towards the second implant region 218. When the ratio is greater than 0.5, the heavily p-doped region 228 would be too close to the second implant region 218 so that all electric field lines are concentrated right between the heavily p-doped region 228 and the second implant region 218. As a result, an excessive deep heavily p-doped region 228 cannot drive the photon electrons distributed across the entire germanium layer 224.

Referring to FIGS. 1 and 10, method 100 includes a block 120 where a dielectric layer 230 is formed over the workpiece 200. In some embodiments, the dielectric layer 230 may be an interlayer dielectric (ILD) layer that is deposited using chemical vapor deposition (CVD), flowable CVD (FCVD), spin-on coating, or a suitable deposition method. The dielectric layer 230 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. Although not explicitly shown in the figures, before the deposition of the dielectric layer 230, a contact etch stop layer (CESL) may be deposited over the workpiece 200. The CESL may include silicon nitride, silicon oxynitride, or other dielectric materials having different etching characteristic than the dielectric layer 230.

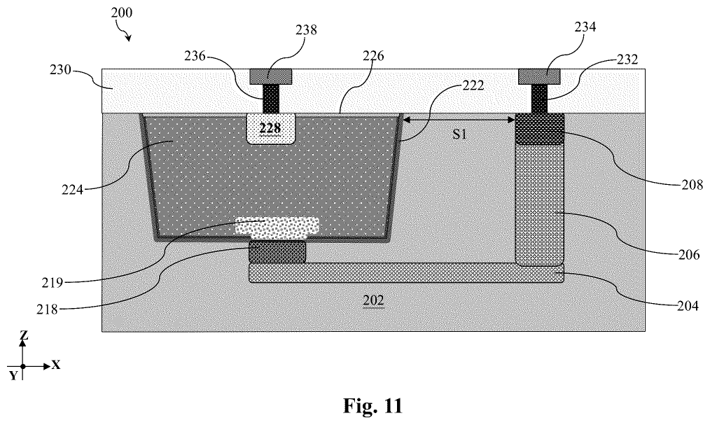

Referring to FIGS. 1 and 11, method 100 includes a block 122 where contact features are formed in the dielectric layer 230 to couple to the heavily n-doped region 208 and the heavily p-doped region 228. As shown in FIG. 11, such contact features may include a first contact via 232 disposed on the heavily n-doped region 208, a first metal line 234 disposed on the first contact via 232, a second contact via 236 disposed on the heavily p-doped region 228, and a second metal line 238 disposed on the second contact via 236. In an example process, a dual-damascene process may be performed to form the openings for the contact via and metal lines and then a metal fill layer is deposited in the via and line openings to form the contact vias and metal lines. In some embodiments, the metal fill layer may include copper (Cu), titanium nitride (TiN), doped polysilicon, cobalt (Co), tungsten (W), nickel (Ni). When the metal fill layer includes copper (Cu), a barrier layer may be deposited along sidewalls of the openings to prevent direct contact of copper and oxygen in the dielectric layer 230. The barrier layer may include titanium nitride, tantalum nitride, manganese nitride, or other transition metal nitride. Although not explicitly shown in the figures, an optional metal silicide feature may be formed between the metal fill layer and the heavily p-doped region 228. The metal silicide feature functions to further reduce contact resistance and may include titanium silicide, nickel silicide, cobalt silicide, or tungsten silicide. It can be

FIGS. 12, 13 and 14 illustrates example alternative embodiments that may be formed using method 100 as well. FIG. 12 illustrates a first alternative image sensor 200-1 where multiple p-type wells are formed in the germanium layer 224 to boost the electron transfer efficiency. In the depicted embodiments, a center p-well 240 and a surrounding p-well 242 are formed in the germanium layer 224. In some embodiments, the surrounding p-well 242 is more heavily doped than the center p-well 240. In some instances, a dopant concentration in the surrounding p-well 242 is between about 1×1018 cm⁻³ and about 1×10²⁰ cm⁻³ while a dopant concentration in the center p-well 240 is between about 1×10¹⁵ cm⁻³ and about 9×10¹⁷ cm⁻³. Due to the p-type dopant gradient, electrons generated by incident photons can be guided from the surrounding p-well 242 toward the center p-well. From there, the photon electrons can travel along the conduction path (the second implant region 218, the deep well 204, the first implant region 206) toward the heavily n-doped region 208.

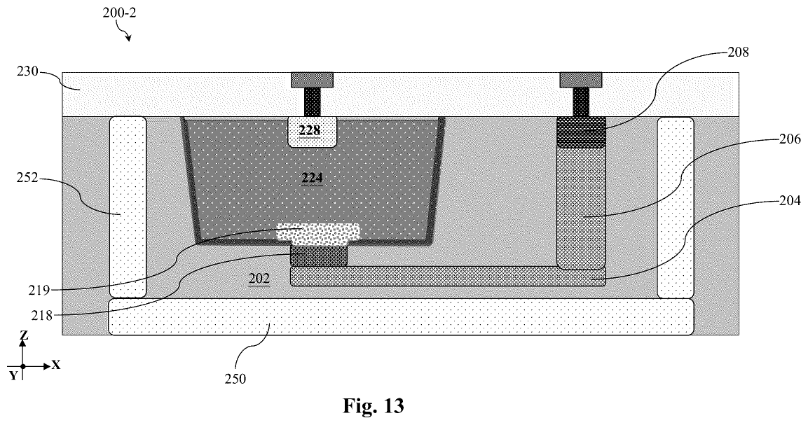

FIG. 13 illustrates a second alternative image sensor 200-2 that includes p-well isolation features. The p-well isolation features include a bottom isolation p-well 250 and a sidewall isolation p-well 252. The sidewall isolation p-well 252 extends completely around the germanium layer 224. The second alternative image sensor 200-2 may be regarded as the image sensor 200 in FIG. 11 being surrounded or caged in by the bottom isolation p-well 250 and the sidewall isolation p-well 252. The bottom isolation p-well 250 and the sidewall isolation p-well 252 include a p-type dopant, such as boron (B) or boron difluoride (BF₂) and a dopant concentration between about 5×10¹⁶ atoms/cm³ (cm⁻³) and about 5×10¹⁸ cm⁻³.

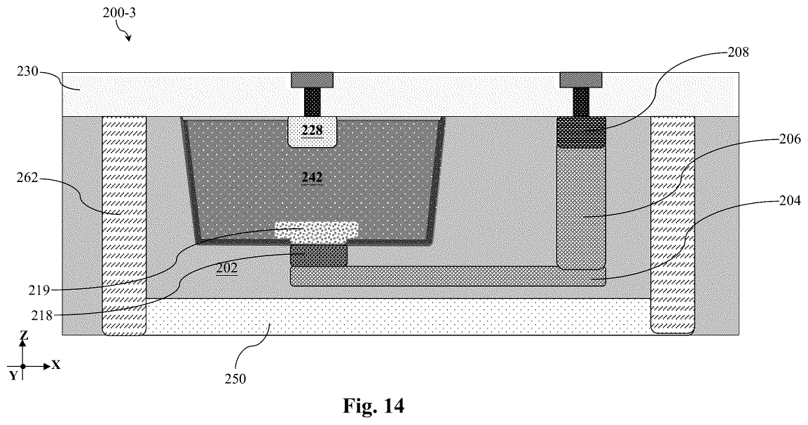

FIG. 14 illustrates a third alternative image sensor 200-3 that includes hybrid isolation features. The hybrid isolation features include a bottom isolation p-well 250 and a sidewall isolation feature 262. The sidewall isolation feature 262 extends completely around the germanium layer 224. The third alternative image sensor 200-3 may be regarded as the image sensor 200 in FIG. 11 being surrounded or caged in by the bottom isolation p-well 250 and the sidewall isolation feature 262. The bottom isolation p-well 250 include a p-type dopant, such as boron (B) or boron difluoride (BF₂) and a dopant concentration between about 5×10¹⁶ atoms/cm³ (cm⁻³) and about 5×10¹⁸ cm⁻³. The sidewall isolation feature 262 may be formed of a dielectric material or a metal. For example, the sidewall isolation feature 262 may include silicon oxide, silicon nitride, titanium nitride, copper, or aluminum.

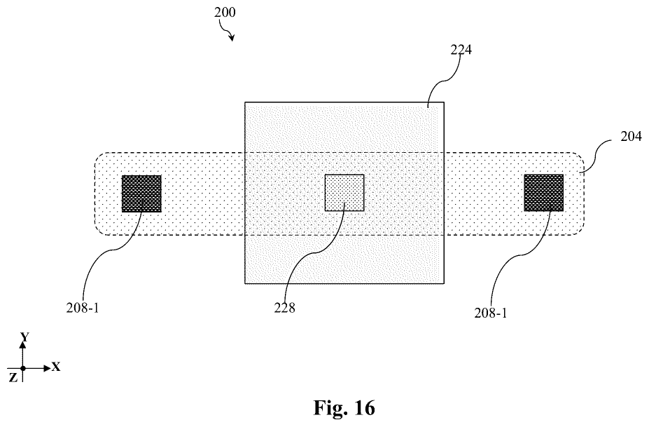

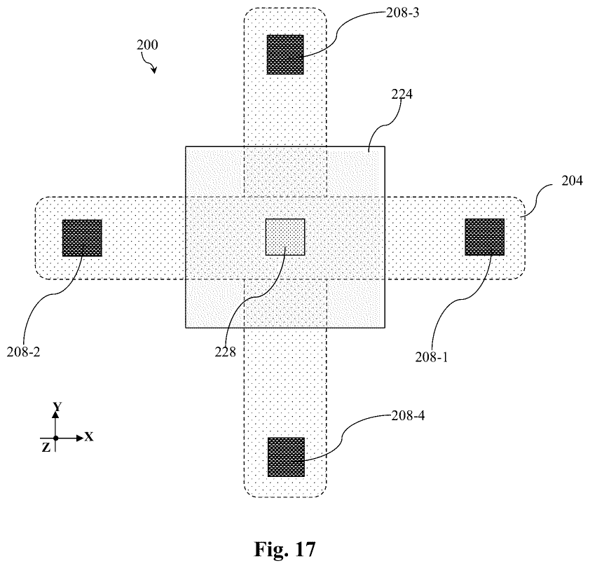

FIGS. 15, 16 and 17 provide schematic top view of the image sensor 200 formed using method 100. For ease of illustration, FIGS. 15, 16, and 17 only illustrate the germanium layer 224, the heavily p-doped region 228, the deep well 204, and the heavily n-doped region 208. In some embodiments illustrated in FIGS. 15, 11, 12, 13, and 14, the deep well 204 is elongated along the X direction and only electrically connect a single heavily n-doped region 208 and the heavily p-doped region 228. The deep well 204 starts from one side of the germanium layer 224, extends below the germanium layer 224, and terminates directly below the germanium layer 224. In some embodiments illustrated in FIG. 16, the deep well 204 extends longer along the X direction such that the germanium layer 224 vertically overlaps a middle portion of the deep well 204 while two end portions are outside the vertical projection area of the germanium layer 224. The deep well 204 in FIG. 16 electrically connects the heavily p-doped region 228 to a first heavily n-doped region 208-1 and a second heavily n-doped region 208-2. In some other embodiments illustrated in FIG. 17, the deep well 204 is cross-shaped or has a plus-sign shape with four arms. While the germanium layer 224 is disposed over a central connection portion of the cross-shaped deep well 204, the four arms reach beyond the vertical projection area of the germanium layer 224. The cross-shaped deep well 204 in FIG. 17 electrically connects the heavily p-doped region 228 to a first heavily n-doped region 208-1, a second heavily n-doped region 208-2, a third heavily n-doped region 208-3, and a fourth heavily n-doped region 208-4. Compared to the embodiment shown in FIG. 15, the embodiments shown in FIGS. 16 and 17 may provide a greater conduction path for the collected photon electrons at a price of pixel size.

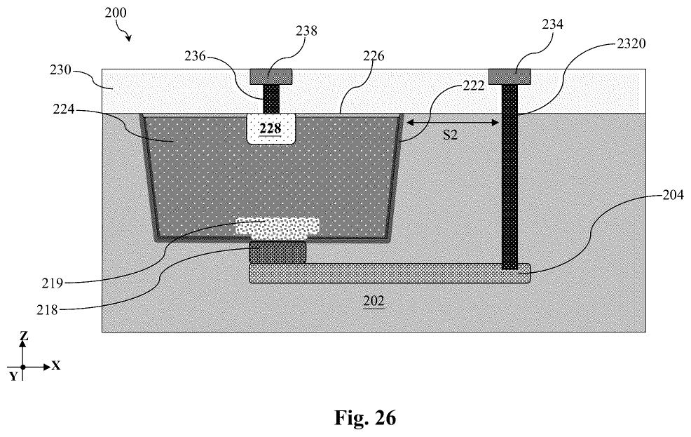

Reference is now made to FIG. 18, which illustrates a flow chart for an alternative method 300. While method 300 shares some common operations with method 100, method 300 is different from method 100 in that it replaces the first implant region 206 and the heavily n-doped region 208 with an extended via 2320 (shown FIG. 26).

Referring to FIGS. 18, 2 and 3, method 300 includes a block 302 where a deep well 204 is formed in a substrate 202 of a workpiece 200. Operations at block 302 are substantially similar to those at block 102. For that reason, detailed description of operations at block 302 is omitted for brevity.

Referring to FIGS. 18 and 19, method 300 includes a block 304 where a cavity 210 is etched in the substrate 202 such that a part of the cavity 210 is directly over the deep well 204. Operations at block 304 are substantially similar to those at block 108. For that reason, detailed description of operations at block 304 is omitted for brevity. Block 304 is at least different from block 108 in that the workpiece 200 at 304 does not include equivalents of the first implant region 206 and the heavily n-doped region 208 formed in the substrate 202. This is so because method 300 does not include operations to form equivalents of the first implant region 206 and the heavily n-doped region 208 before the formation of the cavity 210.

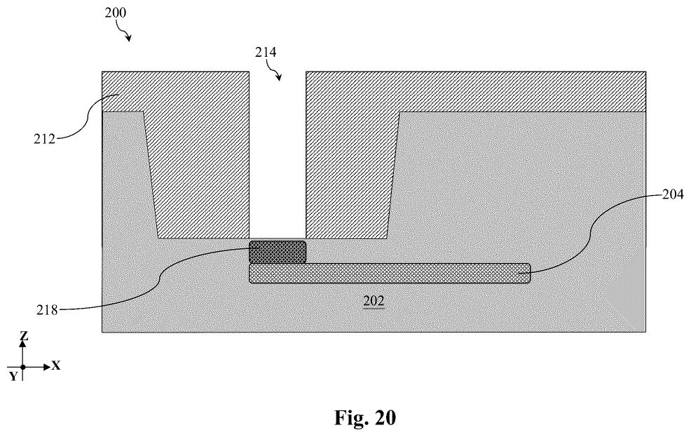

Referring to FIGS. 18 and 20, method 300 includes a block 306 where a second implant region 218 is formed between a bottom surface of the cavity 210 and the deep well 204. Operations at block 306 are substantially similar to those at block 110. For that reason, detailed description of operations at block 306 is omitted for brevity.

Referring to FIGS. 18, 21 and 22, method 300 includes a block 308 where an interfacial implant region 222 is formed along surfaces of the cavity 210. Operations at block 308 are substantially similar to those at block 112. For that reason, detailed description of operations at block 308 is omitted for brevity.

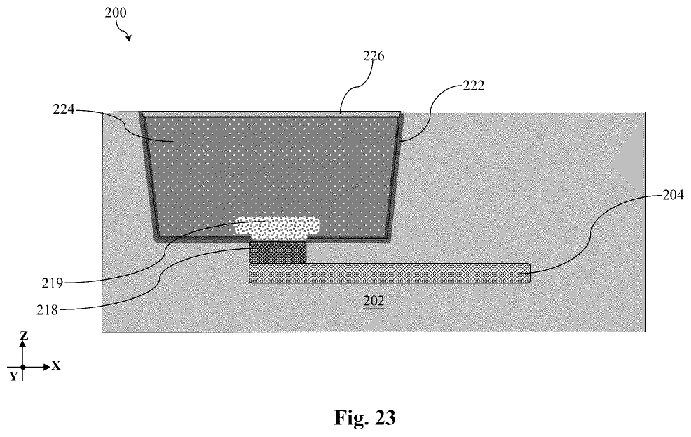

Referring to FIGS. 18 and 23, method 300 includes a block 310 where a germanium layer 224 is formed in the cavity 210. Operations at block 310 are substantially similar to those at block 114. For that reason, detailed description of operations at block 310 is omitted for brevity.

Referring to FIGS. 18 and 23, method 300 includes a block 312 where a cap layer 226 is formed over the germanium layer 224. Operations at block 312 are substantially similar to those at block 116. For that reason, detailed description of operations at block 312 is omitted for brevity.

Referring to FIGS. 18 and 24, method 300 includes a block 314 where a heavily p-doped region 228 is formed through the cap layer 226 and into the germanium layer 224. Operations at block 314 are substantially similar to those at block 118. For that reason, detailed description of operations at block 314 is omitted for brevity.

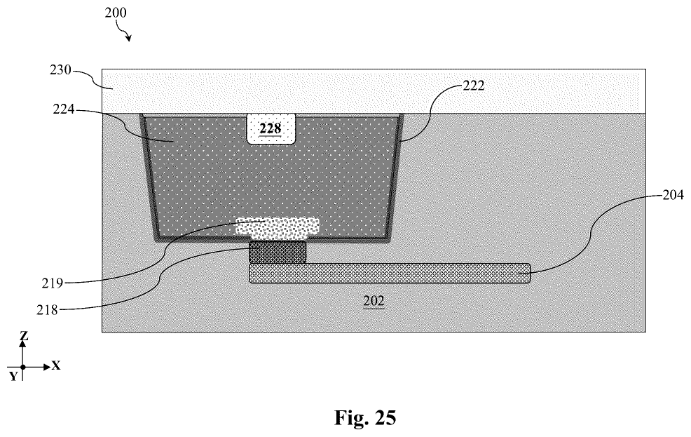

Referring to FIGS. 18 and 25, method 300 includes a block 316 where a dielectric layer 230 is formed over the workpiece 200. Operations at block 316 are substantially similar to those at block 120. For that reason, detailed description of operations at block 316 is omitted for brevity.

Referring to FIGS. 18 and 26, method 300 includes a block 318 where contact features are formed in the dielectric layer 230 to couple to the deep well 204 and the heavily p-doped region 228. As shown in FIG. 26, such contact features may include an extended contact via 2320 disposed on the deep well 204, a first metal line 234 disposed on the extended contact via 2320, a second contact via 236 disposed on the heavily p-doped region 228, and a second metal line 238 disposed on the second contact via 236. In an example process, a dual-damascene process may be performed to form the openings for the contact via and metal lines and then a metal fill layer is deposited in the via and line openings to form the contact vias and metal lines. In some alternative embodiments, the extended contact via 2320 and the second contact via 236 are formed separately. Because the extended contact via 2320 extends much deeper into the substrate 202 than the second contact via 236 into the germanium layer 224, simultaneously etching the via openings may cause substantial over-etching of the heavily p-doped region 228 or even the germanium layer 224. In these alternative embodiments, one of the extended contact via 2320 and the second contact via 236 is formed before the other to avoid over-etching and damages to the germanium layer 224. In some embodiments, the metal fill layer may include copper (Cu), titanium nitride (TiN), doped polysilicon, cobalt (Co), tungsten (W), nickel (Ni). When the metal fill layer includes copper (Cu), a barrier layer may be deposited along sidewalls of the openings to prevent direct contact of copper and oxygen in the dielectric layer 230. The barrier layer may include titanium nitride, tantalum nitride, manganese nitride, or other transition metal nitride. Although not explicitly shown in the figures, an optional metal silicide feature may be formed between the metal fill layer and the heavily n-doped region 208 or the heavily p-doped region 228. The metal silicide feature functions to further reduce contact resistance and may include titanium silicide, nickel silicide, cobalt silicide, or tungsten silicide.

As shown in FIG. 26, the extended contact via 2320 replaces the first implant region 206, the heavily n-doped region 208 and the first contact via 232. Like the features it replaces, it too serves a part of the conduction path of collected photon electrons. Because the extended contact via 2320 is more well defined than the first implant region 206 or the heavily n-doped region 208, its use may reduce the pixel size. Referring back to FIG. 11, the heavily n-doped region 208 may be spaced apart from the germanium layer 224 by a first spacing S1. As shown in FIG. 26, the extended contact via 2320 may be spaced apart from the germanium layer 224 by a second spacing S2. The second spacing S2 is smaller than the first spacing S1.

FIGS. 27, 28 and 29 illustrates example alternative embodiments that may be formed using method 300 as well. FIG. 27 illustrates a fourth alternative image sensor 200-4 where multiple p-type wells are formed in the germanium layer 224 to boost the electron transfer efficiency. In the depicted embodiments, a center p-well 240 and a surrounding p-well 242 are formed in the germanium layer 224. In some embodiments, the surrounding p-well 242 is more heavily doped than the center p-well 240. In some instances, a dopant concentration in the surrounding p-well 242 is between about 1×10¹⁸ cm⁻³ and about 1×10²⁰ cm⁻³ while a dopant concentration in the center p-well 240 is between about 1×10¹⁵ cm⁻³ and about 9×10¹⁷ cm⁻³. Due to the p-type dopant gradient, electrons generated by incident photons can be guided from the surrounding p-well 242 toward the center p-well 240. From there, the photon electrons can travel along the conduction path (the second implant region 218 and the deep well 204) towards the extended contact via 2320.

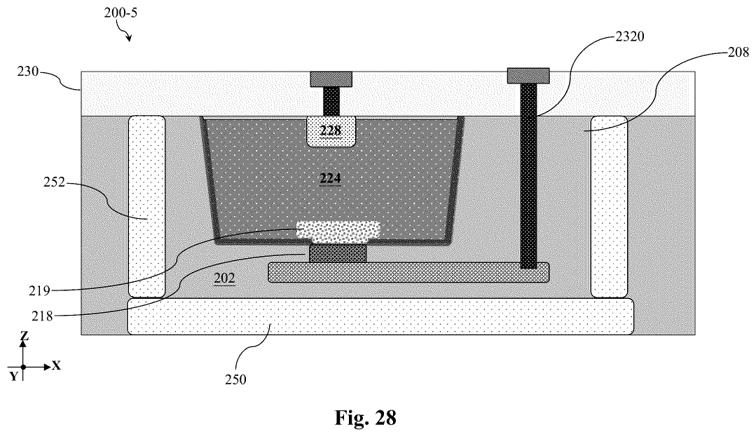

FIG. 28 illustrates a fifth alternative image sensor 200-5 that includes p-well isolation features. The p-well isolation features include a bottom isolation p-well 250 and a sidewall isolation p-well 252. The sidewall isolation p-well 252 extends completely around the germanium layer 224. The fifth alternative image sensor 200-5 may be regarded as the image sensor 200 in FIG. 26 being surrounded or caged in by the bottom isolation p-well 250 and the sidewall isolation p-well 252. The bottom isolation p-well 250 and the sidewall isolation p-well 252 include a p-type dopant, such as boron (B) or boron difluoride (BF₂) and a dopant concentration between about 5×10¹⁶ atoms/cm³ (cm⁻³) and about 5×10¹⁸ cm⁻³.

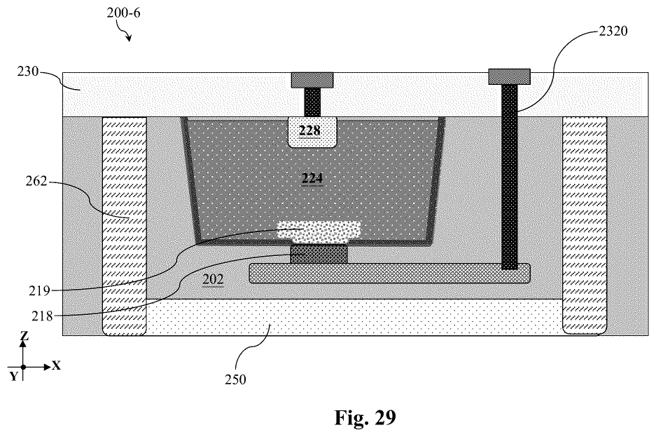

FIG. 29 illustrates a sixth alternative image sensor 200-6 that includes hybrid isolation features. The hybrid isolation features include a bottom isolation p-well 250 and a sidewall isolation feature 262. The sidewall isolation feature 262 extends completely around the germanium layer 224. The sixth alternative image sensor 200-6 may be regarded as the image sensor 200 in FIG. 26 being surrounded or caged in by the bottom isolation p-well 250 and the sidewall isolation feature 262. The bottom isolation p-well 250 include a p-type dopant, such as boron (B) or boron difluoride (BF₂) and a dopant concentration between about 5×10¹⁶ atoms/cm³ (cm⁻³) and about 5×10¹⁸ cm⁻³. The sidewall isolation feature 262 may be formed of a dielectric material or a metal. For example, the sidewall isolation feature 262 may include silicon oxide, silicon nitride, titanium nitride, copper, or aluminum.

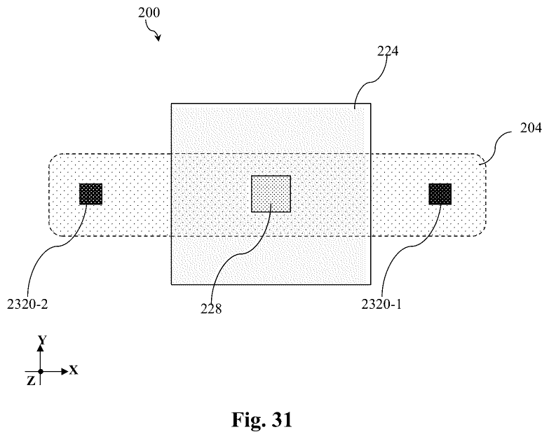

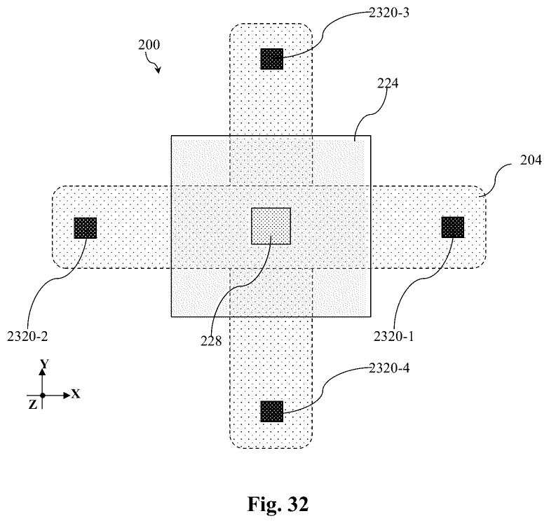

FIGS. 30, 31 and 32 provide schematic top view of the image sensor 200 formed using method 300. For ease of illustration, FIGS. 30, 31, and 32 only illustrate the germanium layer 224, the heavily p-doped region 228, the deep well 204, and the extended contact via 2320. In some embodiments illustrated in FIGS. 30, 26, 27, 28, and 29, the deep well 204 is elongated along the X direction and only electrically connect a single extended contact via 2320 and the heavily p-doped region 228. The deep well 204 starts from one side of the germanium layer 224, extends below the germanium layer 224, and terminates directly below the germanium layer 224. In some embodiments illustrated in FIG. 31, the deep well 204 extends longer along the X direction such that the germanium layer 224 vertically overlaps a middle portion of the deep well 204 while two end portions are outside the vertical projection area of the germanium layer 224. The deep well 204 in FIG. 31 electrically connects the heavily p-doped region 228 to a first extended contact via 2320-1 and a second extended contact via 2320-2. In some other embodiments illustrated in FIG. 32, the deep well 204 is cross-shaped or has a plus-sign shape with four arms. While the germanium layer 224 is disposed over a central connection portion of the cross-shaped deep well 204, the four arms reach beyond the vertical projection area of the germanium layer 224. The cross-shaped deep well 204 in FIG. 32 electrically connects the heavily p-doped region 228 to a first extended contact via 2320-1, a second extended contact via 2320-2, a third extended contact via 2320-3, and a fourth extended contact via 2320-4. Compared to the embodiment shown in FIG. 30, the embodiments shown in FIGS. 31 and 32 may provide a greater conduction path for the collected photon electrons at a price of pixel size.

The image sensors shown in FIGS. 11, 12, 13, 14, 26, 27, 28, and 29 may each constitute a pixel unit in an image sensing array or may be interconnected to function as a macro pixel. Reference is now made to FIGS. 33 and 34. FIG. 33 illustrates an example image sensing array 400 that includes a plurality of pixel units 402. Each of the plurality of pixel units 402 may be implemented using an image sensor similar to the image sensor 200 shown in FIGS. 11, 12, 13, 14, 26, 27, 28, and 29 in FIG. 33. Each of the pixel units 402 can collect photon electrons and send signal by way of signal lines 404. Because each of the pixel units 402 senses incident electromagnetic waves individually, isolation among pixel units 402 can become essential. It follows that the second alternative image sensor 200-2 in FIG. 13, the third alternative image sensor 200-3 in FIG. 14, the fifth alternative image sensor 200-5 in FIG. 28, and the sixth alternative image sensor 200-6 in FIG. 29 may be particularly suitable to implement the pixel units 402 as they include various isolation structures. FIG. 34 illustrates an example macro pixel 500 that includes a plurality of pixel units 502. The pixel units 502 may be implemented using an image sensor similar to the image sensor 200 shown in FIGS. 11, 12, 13, 14, 26, 27, 28, and 29 in FIG. 33. The pixel units 502 can collect photon electrons and collectively send out a signal as a macro pixel. Because signals from the pixel units 502 are lumped together by interconnecting signal lines 504, the pixel units 502 may not need much pixel-to-pixel isolation among pixel units 502. It follows that the image sensor 200 in FIG. 11 or 26, the first alternative image sensor 200-1 in FIG. 12, or the fourth alternative image sensor 200-4 in FIG. 27 may be particularly suitable to implement the macro pixel 500 as they do not include isolation structures and can be made more compact.

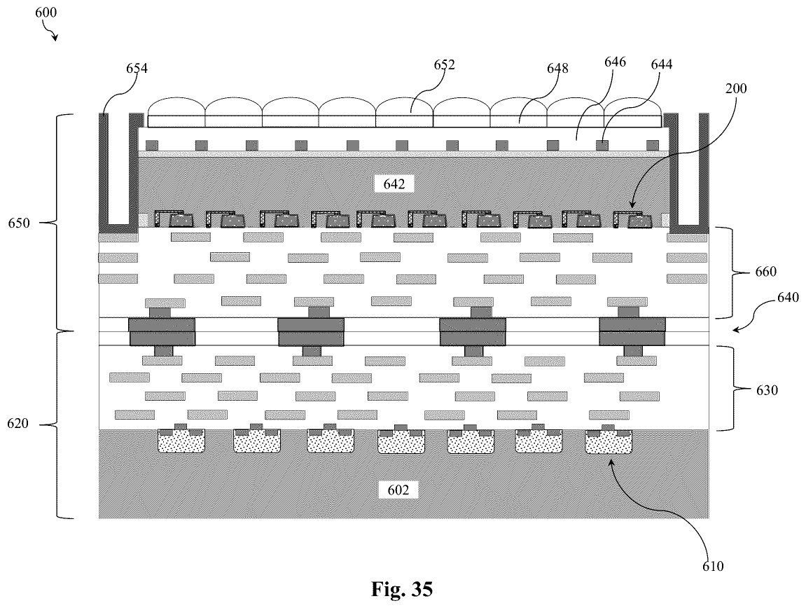

FIG. 35 illustrates an example stacked image sensor 600 that includes an array of image sensors 200. It should be understood that each of the image sensors 200 in FIG. 35 may be the image sensor 200 shown in FIG. 11, the first alternative image sensor 200-1 shown in FIG. 12, the second alternative image sensor 200-2 shown in FIG. 13, the third alternative image sensor 200-3 shown in FIG. 14, the fourth alternative image sensor 200-4 shown in FIG. 27, the fifth alternative image sensor 200-5 shown in FIG. 28, or the sixth alternative image sensor 200-6 shown in FIG. 29. Referring to FIG. 35, the stacked image sensor 600 includes an application-specific integrated circuit (ASIC) die 620 and an image sensor die 650 disposed over and bonded to the ASIC die 620. The ASIC die 620 includes a first substrate 602 and a first interconnect structure 630 disposed on the first substrate 602. The image sensor die 650 includes a second interconnect structure 660 and a second substrate 642 disposed on and bonded to the second interconnect structure 660. The first substrate 602 includes a plurality of transistors 610 formed thereon. The transistors 610 may be planar devices or multi-gate devices. A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

Each of the first interconnect structure 630 and the second interconnect structure 660 includes a plurality of conductive features embedded into a plurality of intermetal dielectric (IMD) layers. The conductive features include metal wires and contact vias. The metal wires provide horizontal signal transmission and the contact vias provide vertical connection. The conductive features may include copper (Cu) and may be spaced apart from the IMD layers by barrier layers. The barrier layers may include a metal nitride, such as titanium nitride. For ease of illustrations, only metal wires are shown. While the first interconnect structure 630 and the second interconnect structure 650 are each shown to include 4 metallization layers, each of them may include four (4) to nineteen (19) metallization layers. The image sensor die 650 and the ASIC die 620 are bonded by way of a bonding structure 640 which may include bonding layers that include vertically aligned bonding pads.

The image sensor die 650 further includes a metal grid 644 disposed over the second substrate 642, including over the image sensors 200. While not explicitly shown in FIG. 35, the second substrate 642 may include deep trench isolation (DTI) features that provide partition for different image sensors 200. The metal grid 644 is disposed in a passivation structure 646, which may include silicon oxide, silicon nitride, silicon oxynitride, or a combination thereof. The image sensor die 650 also includes a color filter array 648 disposed on the passivation structure 646 and microlens features 652 disposed on the color filter array 648. The image sensor die 650 also includes pad structures 654 that are formed along scribe lines of the image sensor die 650.

In one aspect, an image sensor is provided. The image sensor includes a silicon substrate, a germanium region disposed in the silicon substrate, a doped semiconductor isolation layer disposed between the silicon substrate and the germanium region, a heavily p-doped region disposed on the germanium region, a heavily n-doped region disposed on the silicon substrate, a first n-type well disposed immediately below the germanium region, a second n-type well disposed immediately below the heavily n-doped region, and a deep n-type well disposed below and in contact with the first n-type well and the second n-type well.

In some embodiments, the doped semiconductor isolation layer includes silicon and a p-type dopant. In some implementations, the image sensor further includes a semiconductor cap layer disposed on the germanium region. In some instances, top surfaces of the semiconductor cap layer and the silicon substrate are substantially coplanar. In some embodiments, the heavily p-doped region extends through the semiconductor cap layer. In some implementations, the germanium region includes a first p-type well disposed on the first n-type well, and a second p-type well surrounding the first p-type well. In some instances, the first p-type well and the second p-type well include a p-type dopant and a concentration of the p-type dopant in the first p-type well is smaller than a concentration of the p-type dopant in the second p-type well. In some embodiments, the heavily n-doped region is spaced apart from the germanium region by a portion of the silicon substrate.

In another aspect, an image sensor structure is provided. The image sensor structure includes a silicon substrate, a germanium region disposed in the silicon substrate, a heavily p-doped region disposed on the germanium region, an n-type well disposed immediately below the germanium region, a metal contact feature extending into the silicon substrate, and a deep n-type well disposed below and in contact with both the n-type well and the metal contact feature.

In some embodiments, the image sensor structure further includes a doped semiconductor isolation layer disposed between the silicon substrate and the germanium region. In some implementations, the doped semiconductor isolation layer includes boron-doped silicon (Si:B). In some embodiments, the image sensor structure further includes a semiconductor cap layer disposed on the germanium region. In some instances, the semiconductor cap layer consists essentially of silicon. In some instances, the heavily p-doped region extends through the semiconductor cap layer and partially into the germanium region. In some embodiments, the image sensor structure further includes a bottom isolation p-type well disposed below the deep n-type well.

In still another aspect, a method is provided. The method includes forming a deep n-type well in a silicon substrate, forming a first n-type well through the silicon substrate to reach the deep n-type well, forming a heavily n-doped region on the first n-type well, forming a cavity in the silicon substrate such that at least a portion of the cavity is disposed directly over the deep n-type well and that the cavity is spaced apart from the first n-type well, forming a second n-type well between a bottom surface of the cavity and the deep n-type well, forming a p-type isolation layer on surfaces of the cavity, after the forming of the p-type isolation layer, depositing a germanium layer in the cavity, forming a silicon cap over top surfaces of the germanium layer, and forming a heavily p-doped region through the silicon cap to terminate in the germanium layer.

In some embodiments, the method further includes depositing a dielectric layer over the heavily p-doped region and the heavily n-doped region, and forming a first contact feature and a second contact feature through the dielectric layer to contact the heavily p-doped region and the heavily n-doped region, respectively. In some implementations, the forming of the second n-type well includes forming a first patterned photoresist layer to cover a first portion of the bottom surface of the cavity and expose a second portion of the bottom surface of the cavity, and implanting an n-type dopant in the second portion using the first patterned photoresist layer as an implantation mask. In some instances, the forming of the p-type isolation layer includes removing the first patterned photoresist layer, forming a second patterned photoresist layer to cover the second portion of the bottom surface of the cavity and expose the first portion of the bottom surface of the cavity, and implanting a p-type dopant in the first portion using the second patterned photoresist layer as an implantation mask. In some embodiments, the deep n-type well is elongated and includes a first end portion, a second end portion, and a middle portion sandwiched between the first end portion and the second end portion. The germanium layer is disposed directly over the middle portion but does not overly the first end portion and the second end portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a silicon substrate;
a germanium region disposed in the silicon substrate;
a doped semiconductor isolation layer disposed between the silicon substrate and the germanium region;
a heavily p-doped region disposed on the germanium region;
a heavily n-doped region disposed on the silicon substrate;
a first n-type well disposed immediately below the germanium region;
a second n-type well disposed immediately below the heavily n-doped region; and
a deep n-type well disposed below and in contact with the first n-type well and the second n-type well.

2. The image sensor of claim 1, wherein the doped semiconductor isolation layer comprises silicon and a p-type dopant.

3. The image sensor of claim 1, further comprising a semiconductor cap layer disposed on the germanium region.

4. The image sensor of claim 3, wherein top surfaces of the semiconductor cap layer and the silicon substrate are substantially coplanar.

5. The image sensor of claim 3, wherein the heavily p-doped region extends through the semiconductor cap layer.

6. The image sensor of claim 1, wherein the germanium region comprises:
a first p-type well disposed on the first n-type well; and
a second p-type well surrounding the first p-type well.

7. The image sensor of claim 6,
wherein the first p-type well and the second p-type well comprise a p-type dopant,
wherein a concentration of the p-type dopant in the first p-type well is smaller than a concentration of the p-type dopant in the second p-type well.

8. The image sensor of claim 1, wherein the heavily n-doped region is spaced apart from the germanium region by a portion of the silicon substrate.

9. An image sensor structure, comprising:
a silicon substrate;
a germanium region disposed in the silicon substrate;
a heavily p-doped region disposed on the germanium region;
an n-type well disposed immediately below the germanium region;
a metal contact feature extending into the silicon substrate; and
a deep n-type well disposed below and in contact with both the n-type well and the metal contact feature.

10. The image sensor structure of claim 9, further comprising:
a doped semiconductor isolation layer disposed between the silicon substrate and the germanium region.

11. The image sensor structure of claim 10, wherein the doped semiconductor isolation layer comprises boron-doped silicon (Si:B).

12. The image sensor structure of claim 9, further comprising a semiconductor cap layer disposed on the germanium region.

13. The image sensor structure of claim 12, wherein the semiconductor cap layer consists essentially of silicon.

14. The image sensor structure of claim 12, wherein the heavily p-doped region extends through the semiconductor cap layer and partially into the germanium region.

15. The image sensor structure of claim 9, further comprising:
a bottom isolation p-type well disposed below the deep n-type well.

16. A method, comprising:
forming a deep n-type well in a silicon substrate;
forming a first n-type well through the silicon substrate to reach the deep n-type well;
forming a heavily n-doped region on the first n-type well;
forming a cavity in the silicon substrate such that at least a portion of the cavity is disposed directly over the deep n-type well and that the cavity is spaced apart from the first n-type well;
forming a second n-type well between a bottom surface of the cavity and the deep n-type well;
forming a p-type isolation layer on surfaces of the cavity;
after the forming of the p-type isolation layer, depositing a germanium layer in the cavity;
forming a silicon cap over top surfaces of the germanium layer; and
forming a heavily p-doped region through the silicon cap to terminate in the germanium layer.

17. The method of claim 16, further comprising:
depositing a dielectric layer over the heavily p-doped region and the heavily n-doped region; and
forming a first contact feature and a second contact feature through the dielectric layer to contact the heavily p-doped region and the heavily n-doped region, respectively.

18. The method of claim 16, wherein the forming of the second n-type well comprises:
forming a first patterned photoresist layer to cover a first portion of the bottom surface of the cavity and expose a second portion of the bottom surface of the cavity; and
implanting an n-type dopant in the second portion using the first patterned photoresist layer as an implantation mask.

19. The method of claim 18, wherein the forming of the p-type isolation layer comprises:
removing the first patterned photoresist layer;
forming a second patterned photoresist layer to cover the second portion of the bottom surface of the cavity and expose the first portion of the bottom surface of the cavity; and
implanting a p-type dopant in the first portion using the second patterned photoresist layer as an implantation mask.

20. The method of claim 16,
wherein the deep n-type well is elongated and includes a first end portion, a second end portion, and a middle portion sandwiched between the first end portion and the second end portion,
wherein the germanium layer is disposed directly over the middle portion but does not overly the first end portion and the second end portion.
